(19) United States
(12) Patent Application Publication
(10) Pub. No.: US 2026/0223297 A1
(43) Pub. Date: Jul. 30, 2026

(54) METHOD OF MANUFACTURING SUBSTRATE HAVING THROUGH-VIA

(71) Applicant: KOREA ELECTRONICS TECHNOLOGY INSTITUTE, Seongnam-si (KR)

(72) Inventors: Je In YU, Seoul (KR); Jong Min YOOK, Seongnam-si (KR); Soo Bin PARK, Seongnam-si (KR)

(21) Appl. No.: 19/451,672

(22) Filed: Jan. 16, 2026

(30) Foreign Application Priority Data
Jan. 24, 2025 (KR) 10-2025-0011644

(51) Int. Cl. H05K 3/42; H05K 3/24; H10W 20/00

(52) U.S. Cl. CPC H05K 3/42; H05K 3/241; H10W 20/0261

(57) ABSTRACT

Disclosed is a method of manufacturing a substrate having a through-via, including forming a through-hole extending through upper and lower surfaces of a substrate, forming an insulating layer having electrical insulation properties covering the surface of the substrate and the inner surface of the through-hole, forming a seed layer of an electrically conductive material on the insulating layer, filling the through-hole of the substrate with a metal and forming a metal layer on the upper and lower surfaces of the substrate, and leaving the metal with which the through-hole is filled and removing the metal layer and the seed layer formed on the upper and lower surfaces of the substrate by electropolishing the substrate, thus preventing etching of the metal with which the through-hole is filled, thereby maintaining electrical characteristics as well as structural stability of an electrical connection medium formed in the through-via.

### CROSS REFERENCE TO RELATED APPLICATION

The present application claims priority to Korean Patent Application No. 10-2025-0011644, filed January 24, 2025, the entire contents of which are incorporated herein for all purposes by this reference.

### TECHNICAL FIELD

The present disclosure relates to a method of manufacturing a substrate having a through-via, which may be used for semiconductor packaging, display devices, high-performance electronic devices, and the like.

### BACKGROUND

In general, a through-via refers to technology in which a through-hole is formed in a substrate and the through-hole is filled with a metal to provide electrical connection, such as for electrodes. As substrates for such through-vias, glass substrates or silicon substrates are typically used, and the through-vias are collectively referred to as through-glass vias (TGVs) or through-silicon vias (TSVs) depending on the type of substrate.

However, conventional techniques for forming through-glass vias (TGVs) or through-silicon vias (TSVs) have several limitations and problems during the process. The technical limitations and problems of the conventional techniques will be described with reference to a through-glass via (TGV) as an exemplary case.

First, in a post-processing process of removing the metal layer (e.g., Cu) formed on the surface after performing a through-glass via (TGV) process, there is a problem in that selective removal between the metal layer on the surface and the metal with which the through-glass via (TGV), namely the through-hole, is filled is difficult. When applying the post-processing process such as chemical mechanical polishing (CMP), metal particles that fall during removal of the metal layer formed on the surface may cause microscopic damage to the glass surface, and microcracks may be generated due to physical pressure.

Additionally, glass may be manufactured to have a structure in which a predetermined stress remains on a surface thereof as the glass cools from a high temperature during the manufacturing process, or may be formed by strengthening the surface through chemical strengthening, and such a strengthened layer may be removed by physically grinding the surface through chemical mechanical polishing (CMP).

Furthermore, in such processes, there is a high likelihood that removed metal residues may remain on the surface of the glass substrate or inside the through-glass via (TGV), thereby causing contamination problems. Contamination may cause defects in subsequent processes and reduce the reliability of the overall manufacturing process. Also, due to differences in physical and chemical properties between the glass substrate and the metal layer, there are difficulties in optimizing the process, and costs are increased.

### SUMMARY

An aspect of the present disclosure is to provide a method of manufacturing a substrate having a through-via, capable of maintaining electrical characteristics as well as structural stability of an electrical connection medium formed in the through-via by preventing etching of metal with which the through-hole is filled.

Another aspect of the present disclosure is to provide a method of manufacturing a substrate having a through-via, capable of controlling and performing selective removal between metal with which the through-hole is filled and metal formed on the surface of the substrate using an electropolishing (EP) process.

Still another aspect of the present disclosure is to provide a method of manufacturing a substrate having a through-via, capable of efficiently removing a metal layer located on the surface of the substrate during an electropolishing process by forming an insulating layer on the surface of the substrate.

An aspect of the present disclosure provides a method of manufacturing a substrate having a through-via, including forming a through-hole extending through upper and lower surfaces of a substrate, forming an insulating layer having electrical insulation properties covering a surface of the substrate and an inner surface of the through-hole, forming a seed layer of an electrically conductive material on the insulating layer, filling the through-hole of the substrate with a metal and forming a metal layer on the upper and lower surfaces of the substrate, and leaving the metal with which the through-hole is filled and removing the metal layer and the seed layer formed on the upper and lower surfaces of the substrate by electropolishing the substrate.

According to one embodiment, forming the insulating layer having electrical insulation properties may include forming the insulating layer as an inorganic insulating film.

According to one embodiment, removing the metal layer and the seed layer formed on the upper and lower surfaces of the substrate by electropolishing the substrate may include connecting the metal layer on the surface of the substrate to an anode of a power supply and connecting a cathode of the power supply to an electrode in an electropolishing bath in which an electropolishing solution is stored, immersing the substrate connected to the power supply in the electropolishing bath in which the electropolishing solution is stored, and operating the power supply to induce ionization of the metal layer and the seed layer formed on the surface of the substrate and remove the same.

According to one embodiment, removing the metal layer and the seed layer formed on the upper and lower surfaces of the substrate by electropolishing the substrate may be performed until the insulating layer formed on the surface of the substrate is exposed.

According to one embodiment, immersing the substrate connected to the power supply in the electropolishing bath in which the electropolishing solution is stored may include immersing the substrate in the electropolishing bath starting from an end opposite to an end of the substrate connected to the anode, thereby preventing non-uniform polishing or short-circuiting during electropolishing.

According to one embodiment, immersing the substrate connected to the power supply in the electropolishing bath in which the electropolishing solution is stored may include immersing the substrate in the electropolishing bath after performing selective masking on the surface of the substrate.

According to one embodiment, leaving the metal with which the through-hole is filled and removing the metal layer and the seed layer formed on the upper and lower surfaces of the substrate by electropolishing the substrate may include connecting the metal layer on the surface of the substrate to an anode of a power supply and connecting a cathode of the power supply to an electrode in an electropolishing bath in which an electropolishing solution is stored, immersing the substrate connected to the power supply in the electropolishing bath in which the electropolishing solution is stored such that the substrate and the electrode are disposed to face each other, arranging a mask between the substrate and the electrode disposed to face each other, and operating the power supply to control an electric field distribution in the electropolishing solution through the mask and to induce ionization of the metal layer and the seed layer formed on the surface of the substrate and remove the same.

According to one embodiment, the mask may include a rectangular base frame and an opening formed in the base frame.

According to one embodiment, removing the metal layer and the seed layer formed on the upper and lower surfaces of the substrate by electropolishing the substrate may include disposing, in the electropolishing bath, the substrate including the metal layer connected to the anode of the power supply and the electrode connected to the cathode of the power supply with a size ratio between the substrate and the electrode being differently adjusted, and controlling an electric field distribution in the electropolishing solution during electropolishing by operation of the power supply, thereby adjusting an etching rate.

According to one embodiment, removing the metal layer and the seed layer formed on the upper and lower surfaces of the substrate by electropolishing the substrate may include varying a shape of the electrode connected to the cathode of the power supply, and controlling an electric field distribution in the electropolishing solution during electropolishing by operation of the power supply, thereby adjusting an etching rate.

The features and advantages of the present disclosure will become more apparent from the following detailed description based on the accompanying drawings.

Before the present disclosure is described in more detail, it must be noted that the terms and words used in the present specification and claims should not be interpreted as being limited to typical meanings or dictionary definitions, but should be interpreted as having meanings and concepts relevant to the technical spirit of the present disclosure based on the rule according to which an inventor may appropriately define a concept of a term to best describe the method he or she knows for carrying out the disclosure.

According to an embodiment of the present disclosure, etching of metal with which a through-hole is filled can be prevented. Therefore, electrical characteristics as well as structural stability of an electrical connection medium formed in a through-via can be maintained.

According to an embodiment of the present disclosure, selective removal between metal with which the through-hole is filled and metal formed on the surface of a substrate can be performed and controlled using an electropolishing (EP) process.

According to an embodiment of the present disclosure, an insulating layer and a seed layer are formed on the surface of the substrate, thereby leaving the metal with which the through-hole of the substrate is filled and effectively removing the metal layer located on the surface of the substrate during an electropolishing process.

According to an embodiment of the present disclosure, the metal layer formed on the surface of the substrate is removed electrochemically using electropolishing, so that the substrate is not damaged, and flatness can be ensured over the entire area of the substrate having a through-via.

According to an embodiment of the present disclosure, by controlling an electric field distribution in an electropolishing solution during electropolishing, an etching rate can be adjusted and overall etching uniformity on the substrate can be improved.

According to an embodiment of the present disclosure, the use of electropolishing allows for a batch process without limitation on substrate size, thereby reducing mass-production costs in substrate manufacturing.

### BRIEF DESCRIPTION OF THE DRAWINGS

The above and other aspects, features, and other advantages of the present disclosure will be more clearly understood from the following detailed description taken in conjunction with the accompanying drawings, in which:

FIG. 1 shows a process of manufacturing a substrate having a through-via according to one embodiment;

FIG. 2 shows forming a through-hole in a substrate in the process of manufacturing a substrate having a through-via according to one embodiment;

FIG. 3 shows forming an insulating layer on the substrate in the process of manufacturing a substrate having a through-via according to one embodiment;

FIG. 4 shows forming a seed layer in the process of manufacturing a substrate having a through-via according to one embodiment;

FIG. 5 shows filling the through-hole with metal and forming a metal layer on the surface of the substrate in the process of manufacturing a substrate having a through-via according to one embodiment;

FIG. 6 shows removing the metal layer and the seed layer formed on the surface of the substrate in the process of manufacturing a substrate having a through-via according to one embodiment;

FIG. 7 shows removing the metal layer and the seed layer in the process of manufacturing a substrate having a through-via according to one embodiment;

FIG. 8 shows an electropolishing apparatus and an electropolishing process using the same in the process of manufacturing a substrate having a through-via according to one embodiment;

FIG. 9 shows a substrate immersion scheme in the process of manufacturing a substrate having a through-via according to one embodiment;

FIG. 10 shows a scheme for controlling etching through masking during electropolishing in the process of manufacturing a substrate having a through-via according to one embodiment;

FIG. 11 shows a scheme for improving etching uniformity using a mask during electropolishing in the process of manufacturing a substrate having a through-via according to one embodiment;

FIG. 12 shows the structure of the mask used in FIG. 11; and

FIG. 13 shows a principle of preventing etching of metal with which the through-hole is filled in the process of manufacturing a substrate having a through-via according to one embodiment.

### DETAILED DESCRIPTION

Hereinafter, a detailed description will be given of the present disclosure (with reference to the attached drawings). However, these are merely exemplary and the present disclosure is not limited to the specific embodiments described by way of example.

The drawings may be schematic or exaggerated for clarity in describing embodiments.

Herein, the expressions “includes” or “may include”, “has” or “may have” indicate the presence of a feature (e.g., a number, function, operation, or component such as a part), and do not exclude the presence of additional features.

Hereinafter, an embodiment of the present disclosure will be described in detail with reference to the attached drawings.

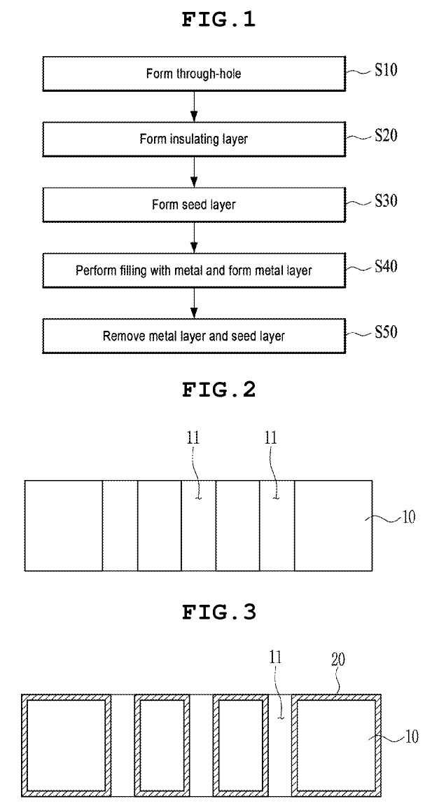

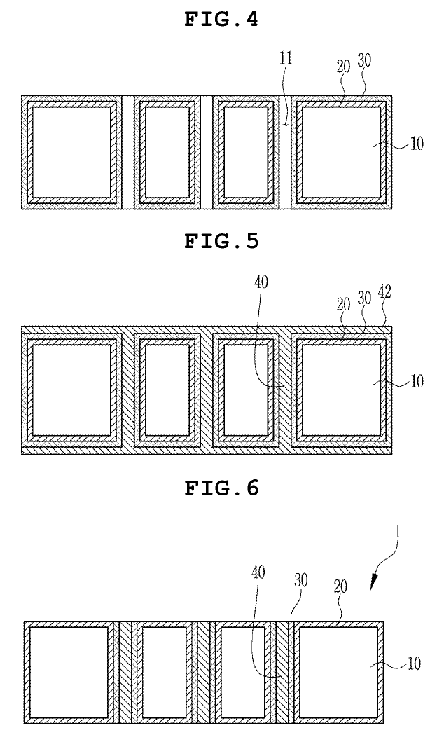

FIG. 1 shows a process of manufacturing a substrate having a through-via according to one embodiment, FIG. 2 shows forming a through-hole in a substrate in the process of manufacturing a substrate having a through-via according to one embodiment, FIG. 3 shows forming an insulating layer on the substrate in the process of manufacturing a substrate having a through-via according to one embodiment, FIG. 4 shows forming a seed layer in the process of manufacturing a substrate having a through-via according to one embodiment, FIG. 5 shows filling the through-hole with metal and forming a metal layer on the surface of the substrate in the process of manufacturing a substrate having a through-via according to one embodiment, and FIG. 6 shows removing the metal layer and the seed layer formed on the surface of the substrate in the process of manufacturing a substrate having a through-via according to one embodiment.

Referring to FIGS. 1 to 6, the method of manufacturing a substrate having a through-via according to the present disclosure may include forming a through-hole 11 extending through the upper and lower surfaces of a substrate 10 (S10), forming an insulating layer 20 having electrical insulation properties covering the surface of the substrate 10 and the inner surface of the through-hole 11 (S20), forming a seed layer 30 of an electrically conductive material on the insulating layer 20 (S30), filling the through-hole 11 of the substrate 10 with a metal 40 and forming a metal layer 42 on the upper and lower surfaces of the substrate 10 (S40), and leaving the metal 40 with which the through-hole 11 is filled and removing the metal layer 42 and the seed layer 30 formed on the upper and lower surfaces of the substrate 10 by electropolishing the substrate 10 (S50).

Forming the through-hole 11 extending through the upper and lower surfaces of the substrate 10 (S10) is a step of forming a through-hole 11 for use in electrical connection, including for electrodes, in the substrate 10, as shown in FIG. 2.

The substrate 10 may be a substrate formed of various materials. The substrate 10 may be a glass substrate or a silicon substrate.

In forming the through-hole 11 extending through the upper and lower surfaces of the substrate 10 (S10), the through-hole 11 may be formed in the substrate 10 using any one selected from among a laser method, a hydrogen fluoride (HF) etching method, and a PNL processing method. The laser method enables the formation of a through-hole 11 in a substrate 10 by emitting a high-energy laser with a short pulse (e.g., a femtosecond laser or the like). The hydrogen fluoride etching method enables the formation of a through-hole 11 by drilling a small hole in a substrate 10 with a laser and widening the hole by additionally performing a chemical etching process using hydrogen fluoride. The PNL processing method enables the physical formation of a through-hole 11 by spraying a fine powder-type abrasive at a high speed onto the surface of a substrate 10.

Forming the insulating layer 20 having electrical insulation properties covering the surface of the substrate 10 and the inner surface of the through-hole 11 (S20) is a step of forming an insulating layer 20 using at least one process selected from among physical vapor deposition (PVD), chemical vapor deposition (CVD), atomic layer deposition (ALD), and electroless plating, as shown in FIG. 3.

In forming the insulating layer 20 having electrical insulation properties covering the surface of the substrate 10 and the inner surface of the through-hole 11 (S20), the insulating layer 20 may be formed as an inorganic insulating film made of an electrically insulating material. In forming the insulating layer 20 having electrical insulation properties covering the surface of the substrate 10 and the inner surface of the through-hole 11 (S20), the insulating layer 20 may be formed of at least one selected from titanium oxide (TiO₂), aluminum oxide (Al₂O₃), zirconia (ZrO₂), zinc oxide (ZnO), silica (SiO₂), mullite (3Al₂O₃·2SiO₂), silicon carbide (SiC), boron nitride (BN), aluminum nitride (AlN), silicon nitride (SixNy), tungsten carbide (WC), and titanium carbide (TiC). In addition, a wider variety of electrically insulating materials may be used.

In forming the insulating layer 20 having electrical insulation properties covering the surface of the substrate 10 and the inner surface of the through-hole 11 (S20), the insulating layer 20 may be formed to a thickness of 300 to 2000 Å. If the thickness of the insulating layer 20 is less than 300 Å, sufficient bonding strength cannot be obtained and a non-uniform insulating layer may be formed. On the other hand, if the thickness of the insulating layer 20 exceeds 2000 Å, internal stress may increase, which may cause cracking or delamination, and the process may be uneconomical due to increased cost and time consumption.

The insulating layer 20 formed by S20 of forming the insulating layer 20 having electrical insulation properties covering the surface of the substrate 10 and the inner surface of the through-hole 11 may function to interrupt electrical connection with the metal 40 with which the through-hole 11 of the substrate 10 is filled during electropolishing. Moreover, the insulating layer 20 may serve as an adhesive layer to stably form the seed layer 30 formed subsequently.

Forming the seed layer 30 of an electrically conductive material on the insulating layer 20 (S30) is a step of forming a seed layer 30 on the insulating layer 20 using at least one process selected from among physical vapor deposition (PVD), chemical vapor deposition (CVD), atomic layer deposition (ALD), and electroless plating, as shown in FIG. 4. The seed layer 30 may serve to cover the surface of the substrate 10 and the inner surface of the through-hole 11.

In forming the seed layer 30 of an electrically conductive material on the insulating layer 20 (S30), the seed layer 30 may be formed of at least one selected from among copper (Cu), gold (Au), silver (Ag), aluminum (Al), calcium (Ca), ruthenium (Ru), rubidium (Rb), magnesium (Mg), palladium (Pd), and alloys thereof, which have excellent electrical conductivity. In addition, a wider variety of electrically conductive materials may be used.

In forming the seed layer 30 of an electrically conductive material on the insulating layer 20 (S30), the seed layer 30 may be formed of copper (Cu) as one example.

In forming the seed layer 30 of an electrically conductive material on the insulating layer 20 (S30), the seed layer 30 may be formed to a thickness of 500 to 10,000 Å. If the thickness of the seed layer 30 is less than 500 Å, sufficient bonding strength cannot be obtained, a non-uniform seed layer may be formed, and the quality of the seed layer may deteriorate. On the other hand, if the thickness of the seed layer 30 exceeds 10,000 Å, internal stress may increase, which may cause cracking or delamination, and excessive etching may occur during the etching process to remove the seed layer, and the process may be uneconomical due to increased cost and time consumption.

Filling the through-hole 11 of the substrate 10 with the metal 40 and forming the metal layer 42 on the upper and lower surfaces of the substrate 10 (S40) is a step of filling the through-hole 11 of the substrate 10 with a metal 40 using a process such as electrolytic plating or electroless plating, as shown in FIG. 5.

In filling the through-hole 11 of the substrate 10 with the metal 40 and forming the metal layer 42 on the upper and lower surfaces of the substrate 10 (S40), the metal layer 42 may be naturally formed on each of the upper and lower surfaces of the substrate 1 during filling the through-hole 11 of the substrate 10 with the metal 40 using a process such as electrolytic plating or electroless plating.

In filling the through-hole 11 of the substrate 10 with the metal 40 and forming the metal layer 42 on the upper and lower surfaces of the substrate 10 (S40), filling with the metal 40 and forming the metal layer 42 may be performed using at least one selected from among copper (Cu), gold (Au), silver (Ag), aluminum (Al), calcium (Ca), ruthenium (Ru), rubidium (Rb), magnesium (Mg), palladium (Pd), and alloys thereof, which have excellent electrical conductivity. In addition, a wider variety of electrically conductive materials may be used.

In filling the through-hole 11 of the substrate 10 with the metal 40 and forming the metal layer 42 on the upper and lower surfaces of the substrate 10 (S40), copper (Cu) may be used as one example.

By filling the through-hole 11 of the substrate 10 with the metal 40 and forming the metal layer 42 on the upper and lower surfaces of the substrate 10 (S40), the metal 40 with which the through-hole 11 of the substrate 10 is filled may be used for electrical connection as an electrical connection medium, including electrodes. The metal 40 with which the through-hole 11 of the substrate 10 is filled may serve as a through-via electrode.

Removing the metal layer 42 and the seed layer 30 formed on the upper and lower surfaces of the substrate 10 by electropolishing the substrate 10 (S50) is a step of completing the manufacture of a substrate 1 having a through-via by leaving the insulating layer 20 on the upper and lower surfaces of the substrate 10 and also leaving the metal 40 with which the through-hole 11 is filled, as shown in FIG. 6. The insulating layer 20 and the seed layer 30 may be left along with the filled metal 40 inside the through-hole 11 of the substrate 10.

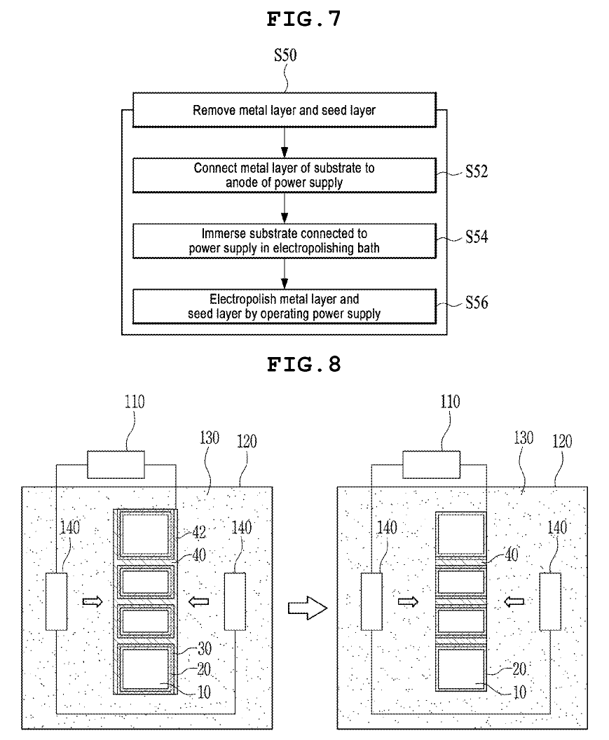

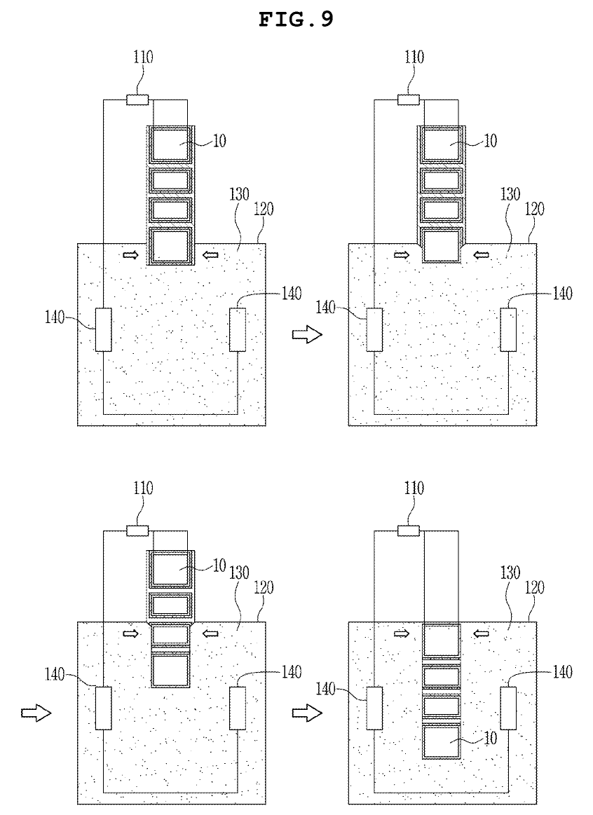

FIG. 7 shows removing the metal layer and the seed layer in the process of manufacturing a substrate having a through-via according to one embodiment, FIG. 8 shows an electropolishing apparatus and an electropolishing process using the same in the process of manufacturing a substrate having a through-via according to one embodiment, and FIG. 9 shows a substrate immersion scheme in the process of manufacturing a substrate having a through-via according to one embodiment.

Referring to FIGS. 7 and 8, in the method of manufacturing a substrate having a through-via according to the present disclosure, removing the metal layer 42 and the seed layer 30 formed on the upper and lower surfaces of the substrate 10 by electropolishing the substrate 10 (S50) may include connecting the metal layer 42 on the surface of the substrate 10 to the anode (+) of a power supply 110 and connecting the cathode (-) of the power supply 110 to the electrode 140 in an electropolishing bath 120 in which an electropolishing solution 130 is stored (S52), immersing the substrate 10 connected to the power supply 110 in the electropolishing bath 120 in which the electropolishing solution 130 is stored (S54), and operating the power supply 110 to induce ionization of the metal layer 42 and the seed layer 30 formed on the surface of the substrate 10 and remove the same (S56).

In connecting the metal layer 42 on the surface of the substrate 10 to the anode (+) of the power supply 110 and connecting the cathode (-) of the power supply 110 to the electrode 140 in the electropolishing bath 120 in which the electropolishing solution 130 is stored (S52), the electropolishing solution may include sulfuric acid, phosphoric acid, or a mixed solution thereof.

In immersing the substrate 10 connected to the power supply 110 in the electropolishing bath 120 in which the electropolishing solution 130 is stored (S54), the substrate 10 may be vertically oriented in a longitudinal direction and immersed in the electropolishing solution 130, as shown in FIG. 8. The entire substrate 10 may be immersed in the electropolishing solution 130 so as to be completely accommodated therein.

Also, in immersing the substrate 10 connected to the power supply 110 in the electropolishing bath 120 in which the electropolishing solution 130 is stored (S54), as shown in FIG. 9, the substrate 10 may be introduced into the electropolishing bath 120 in which the electropolishing solution 130 is stored, starting from an end opposite to an end of the substrate 10 connected to the anode (+) of the power supply 110. With the substrate 10 vertically oriented in a longitudinal direction, an immersion region in the electropolishing bath 120 may be gradually expanded from a lower portion toward an upper portion of the substrate. Briefly, immersion may be performed while gradually increasing the immersion depth of the substrate 10. In the present disclosure, the immersion depth of the substrate 10 may be increased in a constant manner through initial settings, and etching may be sequentially performed through repeated electropolishing.

In the present disclosure, by immersing the substrate 10 while gradually increasing the immersion depth, the following problems that may occur during electropolishing in a state in which the substrate 10 is completely immersed in the electropolishing solution 130 may be solved.

When electropolishing is performed in a state in which the substrate 10 is completely immersed in an electropolishing solution 130, the metal layer 42 formed on the upper and lower surfaces of the substrate 10 may be etched non-uniformly. Due thereto, a short-circuit phenomenon may occur on the substrate 10, and the electrical connection of the substrate 10 may be interrupted during the electropolishing process. In this way, if a short circuit occurs due to non-uniform etching during the electropolishing process, the electrical connection of the substrate 10 may be interrupted, and thus defects may occur in which the metal layer 42 and the seed layer 30 remain on the surface of the substrate 10 without being removed.

Therefore, in the present disclosure, by immersing the substrate 10 while gradually increasing the immersion depth, the phenomenon of the metal layer 42 being non-uniformly etched during electropolishing may be prevented. It is possible to prevent a phenomenon in which a short circuit occurs in the metal layer 42 during electropolishing. It is also possible to prevent the occurrence of defects in which the metal layer 42 and the seed layer 30 remain on the surface of the substrate 10 without being removed.

Operating the power supply 110 to induce ionization of the metal layer 42 and the seed layer 30 formed on the surface of the substrate 10 and remove the same (S56) is a step of applying a voltage through the power supply 110 to concentrate current density on the surface of the substrate 10, thereby inducing dissolution of the metal material by ionization and etching the same.

Operating the power supply 110 to induce ionization of the metal layer 42 and the seed layer 30 formed on the surface of the substrate 10 and remove the same (S56) may be a process of substantially performing electropolishing. The surface of the substrate 10 may be etched by inducing dissolution of the metal material by ionization. This etching may proceed to the metal layer 42 and the seed layer 30 formed of the metal material on the surface of the substrate 10.

In operating the power supply 110 to induce ionization of the metal layer 42 and the seed layer 30 formed on the surface of the substrate 10 and remove the same (S56), etching may proceed to the metal layer 42 and the seed layer 30 on the surface of the substrate 10 through electropolishing. As shown in FIG. 6, etching may proceed to the seed layer 30 corresponding to the metal material on the surface of the substrate 10 to remove the same. The insulating layer 20 and the seed layer 30 may remain along with the filled metal 40 inside the through-hole 11 of the substrate 10.

In operating the power supply 110 to induce ionization of the metal layer 42 and the seed layer 30 formed on the surface of the substrate 10 and remove the same (S56), when the metal layer 42 and the seed layer 30 corresponding to the metal material are removed from the surface of the substrate 10, the electrical connection is interrupted during electropolishing by the insulating layer 20 having electrical insulation properties, and etching on the substrate 10 slows and eventually stops. In the present disclosure, by utilizing the insulating layer 20 having electrical insulation properties, the metal layer 42 and the seed layer 30 corresponding to the metal material may be effectively removed from the surface of the substrate 10 during electropolishing, and since the insulating layer 20 may serve to interrupt the electrical connection with the metal 40 with which the through-hole 11 is filled, the metal 40 inside the through-hole 11 may be prevented from being etched and damaged. Moreover, according to the present disclosure, selective etching and removal on the substrate 10 during electropolishing may be achieved, and surface planarization of the substrate 10 may be performed.

Also, in operating the power supply 110 to induce ionization of the metal layer 42 and the seed layer 30 formed on the surface of the substrate 10 and remove the same (S56), when a method of gradually increasing the immersion depth of the substrate 10 is employed, repeated electropolishing may be carried out. Briefly, local etching may be repeatedly performed on the substrate 10. As such, process conditions such as voltage and current applied to the electropolishing solution 130, composition of the electropolishing solution 130, and processing temperature may be adjusted depending on the immersion depth setting of the substrate 10. Therefore, an etching extent and etching uniformity on the surface of the substrate 10 may be improved.

As described above, in the present disclosure, removing the metal layer 42 and the seed layer 30 formed on the upper and lower surfaces of the substrate 10 by electropolishing the substrate 10 (S50) may be performed until the insulating layer 20 formed on the surface of the substrate 10 is exposed.

In removing the metal layer 42 and the seed layer 30 formed on the upper and lower surfaces of the substrate 10 by electropolishing the substrate 10 (S50), when both the metal layer 42 and the seed layer 30 are removed from the surface of the substrate 10, the current level is greatly reduced, confirming completion of etching by electropolishing.

Therefore, in the present disclosure, a substrate 1 having a through-via with excellent quality may be manufactured by completely removing the metal material formed on the surface of the substrate 10. The substrate 1 having a through-via may be used in various fields such as semiconductor packaging, display devices, and high-performance electronic devices.

In addition, in the present disclosure, only the metal material formed on the surface of the substrate 10 may be effectively removed, and etching of the metal 40 with which the through-hole 11 of the substrate 10 is filled may be prevented. Accordingly, structural stability may be ensured and electrical characteristics may be maintained when the metal 40 with which the through-hole 11 of the substrate 10 is filled is used as an electrical connection medium formed in the through-via or as a through-via electrode.

In addition, in the present disclosure, selective removal between the metal 40 with which the through-hole 11 of the substrate 10 is filled and the metal (metal layer and seed layer) formed on the surface of the substrate 10 may be performed and controlled using the electropolishing (EP) process.

In addition, in the present disclosure, by utilizing electropolishing for etching, the metal layer 42 and the seed layer 30 formed on the surface of the substrate 10 are removed electrochemically, so that there is no damage to the substrate 10, and flatness may be ensured over the entire area of the substrate 1 having a through-via.

In addition, in the present disclosure, by utilizing electropolishing for etching, there is no limitation on the size of the substrate 10 and a batch process may be performed, thereby reducing the mass-production cost in manufacturing the substrate 1 having a through-via.

Meanwhile, in the present disclosure, overall etching uniformity may be improved by adjusting the etching rate of a specific region during electropolishing, which is specified as follows.

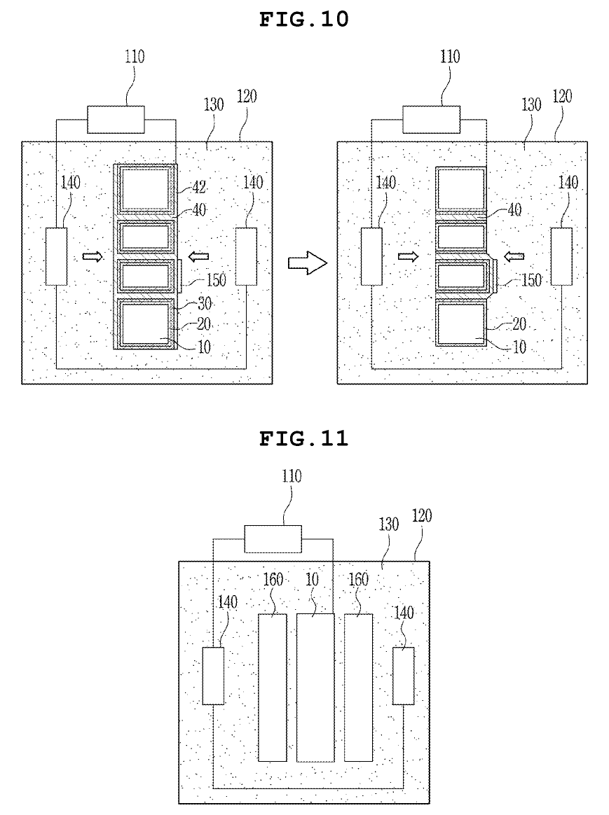

FIG. 10 shows a scheme for controlling etching through masking during electropolishing in the process of manufacturing a substrate having a through-via according to one embodiment.

Referring to FIG. 10, in the present disclosure, in immersing the substrate 10 connected to the power supply 110 in the electropolishing bath 120 in which the electropolishing solution 130 is stored (S54), the substrate 10 may be immersed into the electropolishing bath 120 after performing selective masking 150 on the surface of the substrate 10.

A masking film or the like may be used for masking 150. The selective masking 150 enables the metal layer 42 and the seed layer 30 to be left without being etched during electropolishing. Through such masking 150, an etching rate and an etching extent for a specific region of the substrate 10 may be adjusted.

In addition, in the present disclosure, during electropolishing, an etching rate and an etching extent for a specific region of the substrate 10 may be adjusted by changing an electrode shape or a current supply method, or by applying a pulsed current/voltage.

Therefore, in the present disclosure, etching uniformity for the metal region (metal layer and seed layer) formed on the surface of the substrate 10 during electropolishing may be improved.

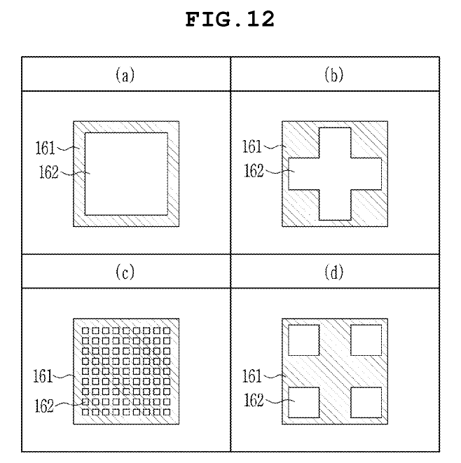

FIG. 11 shows a scheme for improving etching uniformity using a mask during electropolishing in the process of manufacturing a substrate having a through-via according to one embodiment, and FIG. 12 shows the structure of the mask used in FIG. 11. Reference is also made to FIG. 5.

Referring to FIGS. 11 and 12, in the present disclosure, removing the metal layer 42 and the seed layer 30 formed on the upper and lower surfaces of the substrate 10 by electropolishing the substrate 10 (S50) may include connecting the metal layer 42 on the surface of the substrate 10 to the anode (+) of a power supply 110 and connecting the cathode (-) of the power supply 110 to the electrode 140 in an electropolishing bath 120 in which an electropolishing solution 130 is stored, immersing the substrate 10 connected to the power supply 110 in the electropolishing bath 120 in which the electropolishing solution 130 is stored such that the substrate 10 and the electrode 140 are disposed to face each other, arranging a mask 160 between the substrate 10 and the electrode 140 disposed to face each other, and operating the power supply 10 to control an electric field distribution in the electropolishing solution 130 through the mask 160 and to induce ionization of the metal layer 42 and the seed layer 30 formed on the surface of the substrate 10 and remove the same.

As shown in FIG. 12, the mask 160 may include a rectangular base frame 161 and an opening 162 formed in the base frame 161. The base frame 161 may be formed in any one shape selected from among a rectangular frame [(a) of FIG. 12], an inverted cross-shaped frame [(b) of FIG. 12], a mesh-type frame [(c) of FIG. 12], and a cross-shaped frame [(d) of FIG. 12]. Corresponding to the example shapes of the base frame 161, an opening 162 may be formed in the base frame 161. The base frame 161 having any of the above shapes and the opening 162 formed correspondingly are not particularly limited to these shapes and may be formed in more diverse ways.

The mask 160 may serve to control an electric field distribution in the electropolishing solution 130 during electropolishing by operation of the power supply 110 depending on the shape of the opening 162 formed in the base frame 161. By controlling the electric field distribution using the mask 160 in this way, an etching rate for a specific region of the substrate 10 may be adjusted. Therefore, etching uniformity over the entire substrate 10 may be improved.

In addition, in the present disclosure, a size ratio between the substrate 10 including the metal layer 42 connected to the anode (+) of the power supply 110 and the electrode 140 connected to the cathode (-) of the power supply 110 may be adjusted differently, controlling an electric field distribution in the electropolishing solution 130 during electropolishing by operation of the power supply 110. For example, the size ratio between the substrate 10 and the electrode 140 may be differently set to 1:1, 2:1, 1:2, and the like. In this way, by adjusting the size ratio between the substrate 10 and the electrode 140 to induce different electric field distributions, etching rates at the end and central portions of the substrate 10 may be controlled.

In addition, in the present disclosure, the shape of the electrode 140 connected to the cathode (-) of the power supply 110 may be varied, controlling an electric field distribution in the electropolishing solution 130 during electropolishing by operation of the power supply 110.

Therefore, in the present disclosure, the etching rate for a specific region of the substrate 10 may be adjusted by a method selected from among use of the mask 160, adjustment of the size ratio between the substrate 10 and the electrode 140, and adjustment of the shape of the electrode 140. Accordingly, etching uniformity over the entire substrate 10 may be easily improved.

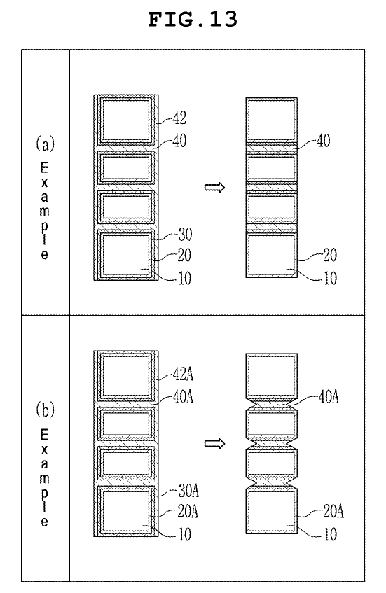

FIG. 13 shows a principle of preventing etching of metal with which the through-hole is filled in the process of manufacturing a substrate having a through-via according to one embodiment. In FIG. 13, (a) shows an example according to the present disclosure, and (b) shows a comparative example.

In FIG. 13, (a) is an example according to the present disclosure, in which an insulating layer 20 and a seed layer 30 are formed on a substrate 10 having a through-hole, the through-hole of the substrate 10 is filled with a metal 40, and a metal layer 42 is formed on the upper and lower surfaces of the substrate 10, and electropolishing is performed, thereby removing the metal layer 42 and the seed layer 30 from the surface of the substrate 10.

Referring to the substrate having a through-via after completion of the electropolishing process in the example according to the present disclosure (the right drawing of the example), both the metal layer 42 and the seed layer 30 formed of the metal material are completely removed from the surface of the substrate 10, and the metal 40 with which the through-hole is filled is preserved intact without being etched. In the example of the present disclosure, when both the metal layer 42 and the seed layer 30 formed of the metal material are removed during electropolishing under the condition that the insulating layer 20 is formed below the seed layer 30, the electrical connection for etching is interrupted by the insulating layer 20, and etching on the substrate 10 slows and eventually stops. Accordingly, when the insulating layer 20 is exposed on the substrate 10, the electrical connection for electropolishing is interrupted, so that the etching process is stopped, and etching of the metal 40 with which the through-hole is filled may be prevented, thereby preventing damage thereto. Structural stability may be significantly ensured during manufacture of a substrate having a through-via. In addition, since there is no damage to the metal 40 with which the through-hole of the substrate 10 is filled, electrical characteristics may be well maintained when the metal 40 is used as a through-via electrode.

In FIG. 13, (b) is a comparative example for explaining the difference from the example, in which an electrically conductive layer 20A and a seed layer 30A are formed on a substrate 10 having a through-hole, the through-hole of the substrate 10 is filled with a metal 40A, and a metal layer 42A is formed on the upper and lower surfaces of the substrate 10, and electropolishing is performed, thereby removing the metal layer 42A and the seed layer 30A from the surface of the substrate 10. As such, the conductive layer 20A may be formed of a metal material such as titanium (Ti) or chromium (Cr).

Referring to the substrate having a through-via after completion of the electropolishing process through the comparative example (the right drawing of the comparative example), both the metal layer 42A and the seed layer 30A formed on the surface of the substrate 10 are removed by electropolishing. However, since the electrical connection is maintained through the conductive layer 20A, etching for electropolishing is continuously performed. Moreover, since the conductive layer 20A maintains electrical connection with the metal 40A with which the through-hole is filled, etching unavoidably proceeds not only through the conductive layer 20A but also into the metal 40A with which the through-hole is filled. Accordingly, damage occurs due to etching to the metal 40A with which the through-hole of the substrate 10 is filled, making it difficult to ensure structural stability in manufacturing a substrate having a through-via. In addition, excessive etching of the metal 40A with which the through-hole of the substrate 10 is filled and damage resulting therefrom occur, thereby causing difficulty in exhibiting electrical characteristics when the metal 40A is used as a through-via electrode. This indicates that a defect occurs in the manufactured product.

Therefore, in the present disclosure, a substrate 1 having a through-via with excellent quality formed may be manufactured by utilizing structural improvement and electropolishing techniques. In particular, the present disclosure is effective at maintaining electrical characteristics as well as structural stability of an electrical connection medium formed in the through-via.

The present disclosure has been described in detail above through specific embodiments. This description is merely an example of applying the principles of the present disclosure, and other configurations may be further included without departing from the scope of the present disclosure.

What is claimed is:

1. A method of manufacturing a substrate having a through-via, comprising:
forming a through-hole extending through upper and lower surfaces of a substrate;
forming an insulating layer having electrical insulation properties covering a surface of the substrate and an inner surface of the through-hole;
forming a seed layer of an electrically conductive material on the insulating layer;
filling the through-hole of the substrate with a metal and forming a metal layer on the upper and lower surfaces of the substrate; and
leaving the metal with which the through-hole is filled and removing the metal layer and the seed layer formed on the upper and lower surfaces of the substrate by electropolishing the substrate.

2. The method according to claim 1, wherein forming the insulating layer having electrical insulation properties comprises forming the insulating layer as an inorganic insulating film.

3. The method according to claim 1, wherein removing the metal layer and the seed layer formed on the upper and lower surfaces of the substrate by electropolishing the substrate comprises:
connecting the metal layer on the surface of the substrate to an anode of a power supply and connecting a cathode of the power supply to an electrode in an electropolishing bath in which an electropolishing solution is stored;
immersing the substrate connected to the power supply in the electropolishing bath in which the electropolishing solution is stored; and
operating the power supply to induce ionization of the metal layer and the seed layer formed on the surface of the substrate and remove the metal layer and the seed layer.

4. The method according to claim 3, wherein removing the metal layer and the seed layer formed on the upper and lower surfaces of the substrate by electropolishing the substrate is performed until the insulating layer formed on the surface of the substrate is exposed.

5. The method according to claim 3, wherein immersing the substrate connected to the power supply in the electropolishing bath in which the electropolishing solution is stored comprises immersing the substrate in the electropolishing bath starting from an end opposite to an end of the substrate connected to the anode, thereby preventing non-uniform polishing or short-circuiting during electropolishing.

6. The method according to claim 3, wherein immersing the substrate connected to the power supply in the electropolishing bath in which the electropolishing solution is stored comprises immersing the substrate in the electropolishing bath after performing selective masking on the surface of the substrate.

7. The method according to claim 1, wherein leaving the metal with which the through-hole is filled and removing the metal layer and the seed layer formed on the upper and lower surfaces of the substrate by electropolishing the substrate comprises:
connecting the metal layer on the surface of the substrate to an anode of a power supply and connecting a cathode of the power supply to an electrode in an electropolishing bath in which an electropolishing solution is stored;
immersing the substrate connected to the power supply in the electropolishing bath in which the electropolishing solution is stored such that the substrate and the electrode are disposed to face each other;
arranging a mask between the substrate and the electrode disposed to face each other; and
operating the power supply to control an electric field distribution in the electropolishing solution through the mask and to induce ionization of the metal layer and the seed layer formed on the surface of the substrate and remove the metal layer and the seed layer.

8. The method according to claim 7, wherein the mask comprises:
a rectangular base frame; and
an opening formed in the base frame.

9. The method according to claim 3, wherein removing the metal layer and the seed layer formed on the upper and lower surfaces of the substrate by electropolishing the substrate comprises disposing, in the electropolishing bath, the substrate comprising the metal layer connected to the anode of the power supply and the electrode connected to the cathode of the power supply with a size ratio between the substrate and the electrode being differently adjusted, and controlling an electric field distribution in the electropolishing solution during electropolishing by operation of the power supply, thereby adjusting an etching rate.

10. The method according to claim 3, wherein removing the metal layer and the seed layer formed on the upper and lower surfaces of the substrate by electropolishing the substrate comprises varying a shape of the electrode connected to the cathode of the power supply, and controlling an electric field distribution in the electropolishing solution during electropolishing by operation of the power supply, thereby adjusting an etching rate.
